(19) United States
(12) Patent Application Publication
(10) Pub. No.: US 2010/0263722 A1
(43) Pub. Date: Oct. 21, 2010

(54) SOLAR CELL AND METHOD OF MANUFACTURING THE SAME

(75) Inventors: Koichi Kubo, Kobe City (JP); Takahiro Mishima, Kobe City (JP)

Correspondence Address: MOTS LAW, PLLC, 1629 K STREET N.W., SUITE 602, WASHINGTON, DC, 20006-1635, US

(73) Assignee: SANYO ELECTRIC CO., LTD., Moriguchi City (JP)

(21) Appl. No.: 12/729,331

(22) Filed: Mar. 23, 2010

(30) Foreign Application Priority Data
Apr. 21, 2009 (JP) 2009-103352

(51) Int. Cl. H01L 31/00; H01L 31/18

(52) U.S. Cl. 136/256; 438/57; 257/E21.09

(57) ABSTRACT

The invention provides a solar cell of increased manufacturing productivity. An aspect of the invention provides a solar cell that comprises a semiconductor substrate having a light-receiving surface and a back surface disposed at the opposite side from the light-receiving surface; a n-type semiconductor region and a p-type semiconductor region both formed on the back surface; and a protection layer formed on the light-receiving surface, the protection layer includes a first surface formed on the semiconductor substrate side and a second surface formed on the opposite side from the first surface, and the second surface has a higher acid-resistance than the first surface.

### CROSS REFERENCE TO RELATED APPLICATIONS

This application claims priority based on 35 USC 119 from prior Japanese Patent Application No. P2009-103352 filed on Apr. 21, 2009, entitled “SOLAR CELL”, the entire contents of which are incorporated herein by reference.

### BACKGROUND OF THE INVENTION

1. Field of the Invention

The invention relates to a back junction solar cell and a method of manufacturing the same.

2. Description of Related Art

Solar cells can convert sunlight, which is clean and is available in unlimited amounts, directly into electricity. Therefore, solar cells are expected as a new energy source.

A so-called back junction solar cell is proposed which includes an n-type semiconductor region and a p-type semiconductor region both of which are formed on the back surface of a substrate. Electrodes are formed on the n-type semiconductor region and on the p-type semiconductor region.

In the processes of manufacturing such a back junction solar cell, the substrate is sometimes subjected to a treatment with an acidic chemical liquid. For example, in a process of forming a semiconductor region on the back-surface side of the substrate, a resist film formed on the back surface of the substrate is patterned using an acidic chemical liquid.

In this case, a light-receiving-surface of the substrate is also treated by the acidic chemical liquid, and thereby may be damaged by the acidic chemical liquid. In particular, in the case that a passivation film, an anti-reflection film, or the like is formed on the light-receiving surface of the substrate, the acidic chemical liquid may deteriorate the passivation film, the anti-reflection film, or the like.

In a disclosed method to address this problem, a protection layer is formed on the light-receiving surface of the substrate before the substrate is subjected to the treatment using an acidic chemical liquid (see, for example, JP-A 2006-128258). A silicon oxide film or the like is used as an example of the protection layer.

The method disclosed in JP-A 2006-128258, however, has its own drawbacks. First, a new protection layer has to be formed every time the substrate is treated with the acidic chemical liquid. Secondly, the protection layer has to be removed before a passivation film, an anti-reflection film, or the like is formed on the light-receiving surface of the substrate.

### SUMMARY OF THE INVENTION

An aspect of the invention provides a solar cell that comprises a semiconductor substrate having a light-receiving surface and a back surface disposed at the opposite side from the light-receiving surface; a n-type semiconductor region and a p-type semiconductor region both formed on the back surface; and a protection layer formed on the light-receiving surface, the protection layer includes a first surface formed on the semiconductor substrate side and a second surface formed on the opposite side from the first surface, and the second surface has a higher acid-resistance than the first surface.

Another aspect of the invention provides a method of manufacturing a solar cell, that comprises steps of: forming a semiconductor substrate having a light-receiving surface and a back surface disposed at the opposite side from the light-receiving surface; forming a n-type semiconductor region and a p-type semiconductor region on the back surface; and forming a protection layer on the light-receiving surface, the forming the protection layer comprising: forming a first surface formed on the semiconductor substrate side; and forming a second surface formed on the opposite side from the first surface, the second surface has a higher acid-resistance than the first surface.

### BRIEF DESCRIPTION OF THE DRAWINGS

FIGS. 1A and 1B are plan views illustrating solar cell 100 according to a first embodiment.

FIG. 2 is an enlarged sectional view taken along A-A line of each of FIGS. 1A and 1B.

FIG. 3 is an enlarged view illustrating a portion of FIG. 2.

FIG. 4 is a view explaining a method of manufacturing solar cell 100 according to the first embodiment.

FIG. 5 is a view explaining the method of manufacturing solar cell 100 according to the first embodiment.

FIG. 6 is a view explaining the method of manufacturing solar cell 100 according to the first embodiment.

FIG. 7 is a view explaining the method of manufacturing solar cell 100 according to the first embodiment.

FIG. 8 is a view explaining the method of manufacturing solar cell 100 according to the first embodiment.

FIG. 9 is a view explaining the method of manufacturing solar cell 100 according to the first embodiment.

FIG. 10 is a view explaining the method of manufacturing solar cell 100 according to the first embodiment.

FIG. 11 is an enlarged sectional view illustrating solar cell 100 according to a second embodiment.

FIG. 12 is a view explaining a method of manufacturing solar cell 100 according to the second embodiment.

FIG. 13 is a view explaining the method of manufacturing solar cell 100 according to the second embodiment.

FIG. 14 is a view explaining the method of manufacturing solar cell 100 according to the second embodiment.

FIG. 15 is a view explaining the method of manufacturing solar cell 100 according to the second embodiment.

FIG. 16 is a view explaining the method of manufacturing solar cell 100 according to the second embodiment.

FIG. 17 is a view explaining the method of manufacturing solar cell 100 according to the second embodiment.

FIG. 18 is a diagram illustrating the relationship between the film thickness of an acid-resistant SiN film and the flow-rate ratio (NH₃/SiH₄).

FIG. 19 is a diagram illustrating the relationship between the refractive index of an acid-resistant SiN film and the flow-rate ratio (NH₃/SiH₄).

FIG. 20 is a diagram illustrating the relationship between the film thickness of an alkali-resistant SiN film and the flow-rate ratio (NH₃/SiH₄).

### DETAILED DESCRIPTION OF EMBODIMENTS

Descriptions are provided for embodiments based on the drawings. In the respective drawings referenced herein, the same constituents are designated by the same reference numerals and duplicate explanation concerning the same constituents is omitted. All of the drawings are provided to illustrate the respective examples only. No dimensional proportions in the drawings shall impose a restriction on the embodiments. For this reason, specific dimensions and the like should be interpreted with the following descriptions taken into consideration. In addition, the drawings include parts whose dimensional relationship and ratios are different from one drawing to another.

Prepositions, such as “on”, “over” and “above” may be defined with respect to a surface, for example a layer surface, regardless of that surface's orientation in space. The preposition “above” may be used in the specification and claims even if a layer is in contact with another layer. The preposition “on” may be used in the specification and claims when a layer is not in contact with another layer, for example, when there is an intervening layer between them.

### First Embodiment

### Configuration of Solar Cell

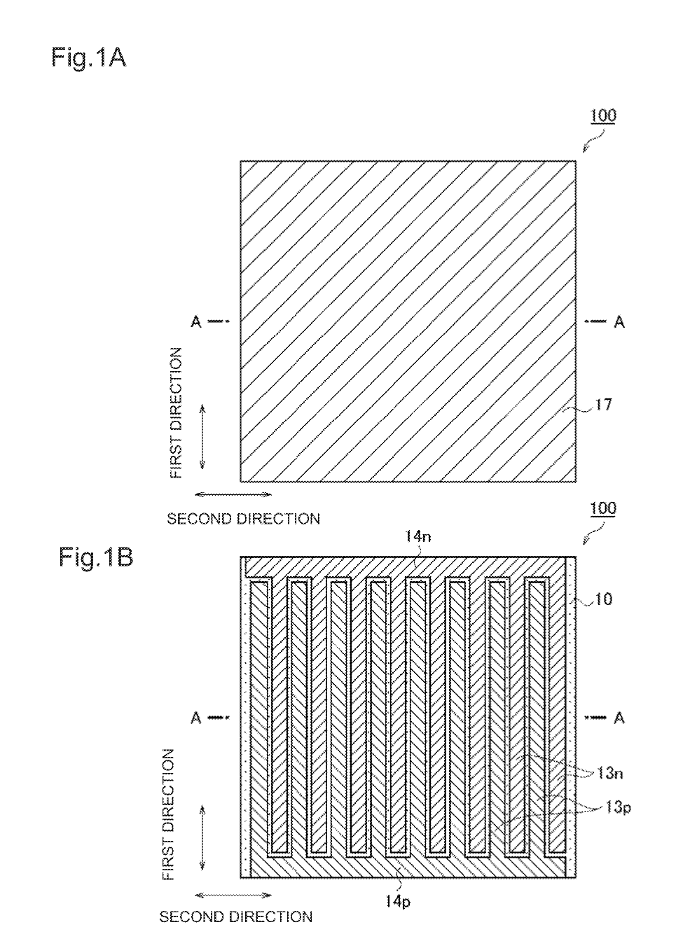

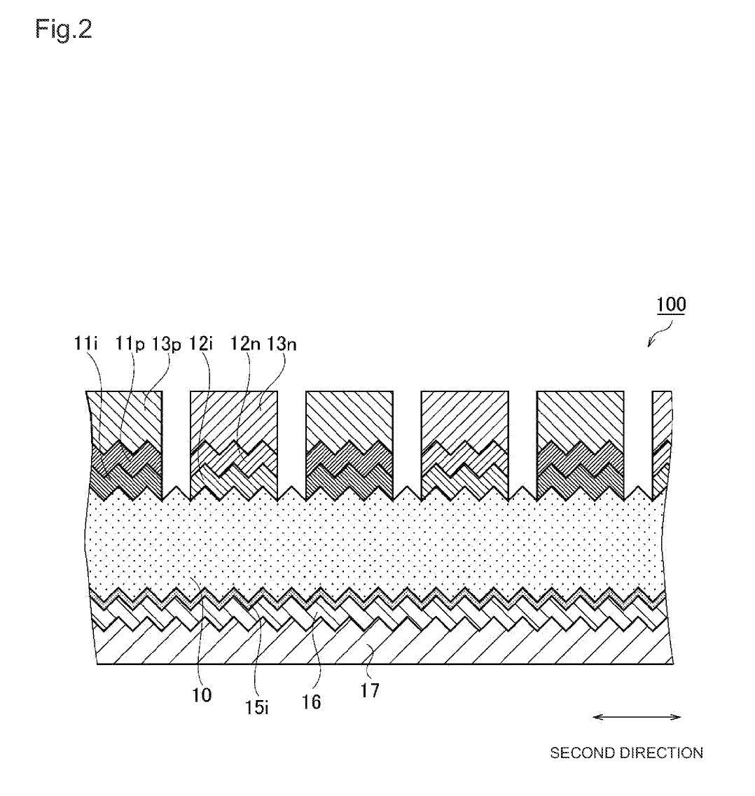

The configuration of a solar cell according to a first embodiment is described by referring to FIGS. 1A, 1B, and 2. FIG. 1A is a plan view illustrating solar cell 100 according to the first embodiment and seen from the light-receiving-surface side. FIG. 1B is a plan view illustrating solar cell 100 according to the first embodiment and seen from the back-surface side. FIG. 2 is an enlarged sectional view taken along A-A line of each of FIGS. 1A and 1B.

As FIGS. 1A, 1B, and 2 show, solar cell 100 includes substrate 10 formed from a semiconductor of either n-type or p-type, i-type amorphous semiconductor layer 11i, p-type amorphous semiconductor layer 11p, i-type amorphous semiconductor layer 12i, n-type amorphous semiconductor layer 12n, p-side fine line-shaped electrodes 13p, n-side fine line-shaped electrodes 13n, p-side connection electrode 14p, n-side connection electrode 14n, i-type amorphous semiconductor layer 15i, amorphous semiconductor layer 16 having the same conductive type as that of the substrate, and protection layer 17.

Solar cell 100 is so-called as a back junction solar cell that includes a p-type semiconductor region and an n-type semiconductor region formed on the back-surface of substrate 10. In the first embodiment, p-type amorphous semiconductor layer 11p corresponds to the “p-type semiconductor region” whereas n-type amorphous semiconductor layer 12n corresponds to the “n-type semiconductor region.”

Substrate 10 has a light-receiving surface that receives sunlight and a back surface that is formed on the opposite side from the light-receiving surface. When the light-receiving surface receives light, substrate 10 generates photogenerated carriers. The “photogenerated carriers” refer to holes and electrons generated when substrate 10 absorbs light. Some materials usable to form substrate 10 are crystalline semiconductor materials, such as monocrystalline Si having a conductive type of either n-type or p-type, polycrystalline Si, and common semiconductor materials including GaAs and InP. Note that substrate 10 of the first embodiment is an n-type semiconductor substrate.

FIG. 2 shows, microscopic asperities (hereinafter, referred to as “textures”) formed both on the light-receiving surface and on the back surface of substrate 10. No structures (e.g., electrodes or the like) that would block the incident light are formed on the light-receiving surface of substrate 10, so that the entire light-receiving surface can absorb incident light.

I-type amorphous semiconductor layer 11i is formed on the back surface of substrate 10 in a comb-tooth-like shape. The comb-tooth-like portions of i-type amorphous semiconductor layer 11i are formed so as to extend in the same direction (hereinafter, referred to as a “first direction”). When i-type amorphous semiconductor layer 11i is formed, no impurities are intentionally introduced into i-type amorphous semiconductor layer 11i. The thickness of i-type amorphous semiconductor layer 11i is such that it does not substantially contribute to electric-power generation. Specifically, the thickness is, for example, in a range from several angstroms to approximately 250 Å.

P-type amorphous semiconductor layer 11p is formed on i-type amorphous semiconductor layer 11i in a comb-tooth-like shape. The comb-tooth-like portions of p-type amorphous semiconductor layer 11p are formed so as to extend in the first direction. P-type amorphous semiconductor layer 11p is a high-concentration p-type region doped with a p-type dopant (e.g., boron, aluminum, or the like). The thickness of p-type amorphous semiconductor layer 11p is, for example, approximately 10 nm.

A structure known as the “HIT structure” is formed by forming i-type amorphous semiconductor layer 11i on n-type substrate 10 and then forming p-type amorphous semiconductor layer 11p on i-type amorphous semiconductor layer 11i. This HIT structure improves the pn junction characteristics.

I-type amorphous semiconductor layer 12i is formed on the back surface of substrate 10 in a comb-tooth-like shape. The comb-tooth-like portions of i-type amorphous semiconductor layer 12i are formed so as to extend in the first direction. When i-type amorphous semiconductor layer 12i is formed, no impurities are intentionally introduced into i-type amorphous semiconductor layer 12i. The thickness of i-type amorphous semiconductor layer 12i is, for example, in a range from several angstroms to approximately 250 Å.

N-type amorphous semiconductor layer 12n is formed on i-type amorphous semiconductor layer 12i in a comb-tooth-like shape. The comb-tooth-like portions of n-type amorphous semiconductor layer 12n are formed so as to extend in the first direction. N-type amorphous semiconductor layer 12n is a high-concentration n-type region doped with an n-type dopant (e.g., phosphorus, or the like). The thickness of n-type amorphous semiconductor layer 12n is, for example, approximately 10 nm.

The comb-tooth-like portions of p-type amorphous semiconductor layer 11p and the comb-tooth-like portions of n-type amorphous semiconductor layer 12n are arranged alternately in a second direction that is substantially orthogonal to the first direction.

A structure known as the back surface field (ESE) structure is formed by forming n-type amorphous semiconductor layer 12n on the back surface of n-type substrate 10. This BSF structure prevents carriers from re-combining together at the interface between the back surface of substrate 10 and n-type amorphous semiconductor layer 12n.

Plural p-side fine line-shaped electrodes 13p are collector electrodes to collect carriers from p-type amorphous semiconductor layer 11p. Plural p-side fine line-shaped electrodes 13p are formed on the comb-tooth-shaped portions of p-type amorphous semiconductor layer 11p. Accordingly, each p-side fine line-shaped electrode 13p is formed so as to extend in the first direction. Each p-side fine line-shaped electrode 13p is formed either as a single metal layer or as a laminate structure of metal layers. For example, each p-side fine line-shaped electrode 13p may include a contact layer formed from Al or the like and formed on p-type amorphous semiconductor layer 11p, and a low-resistivity layer formed from Cu or the like and formed on the contact layer.

Plural n-side fine line-shaped electrodes 13n are collector electrodes to collect carriers from n-type amorphous semiconductor layer 12n. Plural n-side fine line-shaped electrodes 13n are formed on the comb-tooth-shaped portions of n-type amorphous semiconductor layer 12n. Accordingly, each n-side fine line-shaped electrode 13n is formed so as to extend in the first direction. Each n-side fine line-shaped electrode 13n is formed to have a similar configuration as each p-side fine line-shaped electrode 13p.

P-side connection electrode 14p connects wiring materials (not shown) that electrically connect one solar cell 100 to another solar cell 100. As FIG. 1 shows, p-side connection electrode 14p is formed so as to extend in the second direction. P—side connection electrode 14p collects carriers from plural p-side fine line-shaped electrodes 13p.

The wiring materials are connected to N-side connection electrode 14n. As FIG. 1 shows, n-side connection electrode 14n is formed so as to extend in the second direction. N-side connection electrode 14n collects carriers from plural n-side fine line-shaped electrodes 13n.

Though not shown in figures, both n-side connection electrode 14n and p-side connection electrode 14p can be formed so as to have a similar configuration to that of each p-side fine line-shaped electrode 13p described above.

I-type amorphous semiconductor layer 15i is formed so as to cover substantially the entire area of the light-receiving surface of semiconductor substrate 10. When i-type amorphous semiconductor layer 15i is formed, no impurities are intentionally introduced into i-type amorphous semiconductor layer 15i. The thickness of i-type amorphous semiconductor layer 151 is, for example, in a range from several angstroms to approximately 250 Å.

Amorphous semiconductor layer 16 is formed on i-type amorphous semiconductor layer 151. Amorphous semiconductor layer 16 has the same conductive type as that of substrate 10. If substrate 10 is n-type, amorphous semiconductor layer 16 is a high-concentration n-type region doped with an n-type dopant (e.g., phosphorus, or the like). The thickness of amorphous semiconductor layer 16 is, for example, approximately 10 nm.

A structure known as the front surface field (FSF) structure is formed by forming i-type amorphous semiconductor layer 15i on the light-receiving surface of n-type substrate 10 and then forming n-type amorphous semiconductor layer 16 on i-type amorphous semiconductor layer 15i. This FSF structure prevents carriers from re-combining together at the interface between the light-receiving surface of substrate 10 and i-type amorphous semiconductor layer 15i. In the first embodiment, i-type amorphous semiconductor layer 151 and amorphous semiconductor layer 16 together function as a passivation layer.

Protection layer 17 is formed on amorphous semiconductor layer 16. Accordingly, protection layer 17 covers substantially the entire surface of amorphous semiconductor layer 16. Protection layer 17 is formed from, for example, silicon nitride, silicon carbide, various types of resin, and various types of silicon. These materials may be used either individually or in combination.

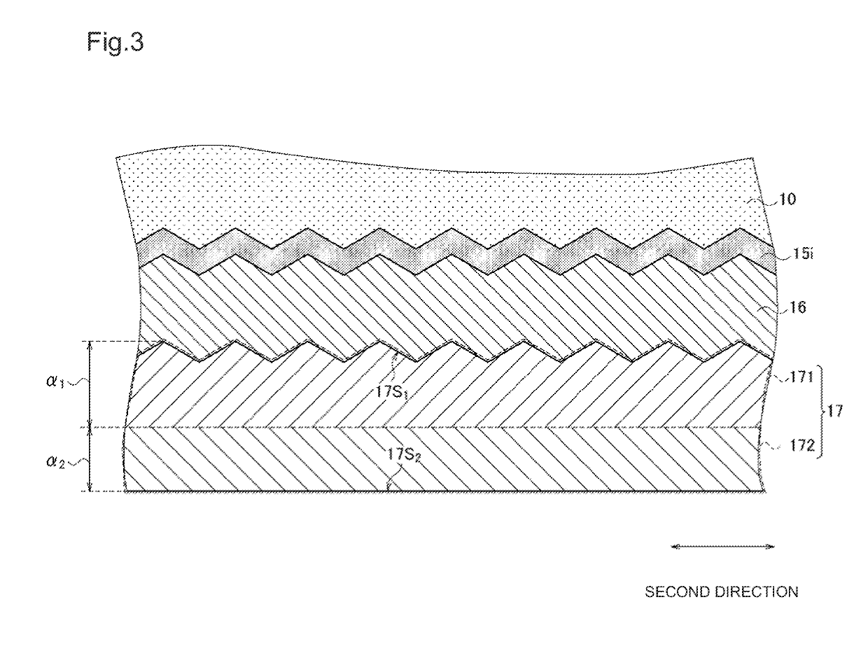

FIG. 3 is an enlarged view illustrating a portion of FIG. 2. As FIG. 3 shows, protection layer 17 includes first region 171 formed on the side adjacent to substrate 10, and second region 172 formed on the opposite side from substrate 10. First region 171 is formed on amorphous semiconductor layer 16, and then second region 172 is formed on first region 171. First region 171 has first surface 17S₁ formed adjacent to substrate 10. Second region 172 has second surface 17S₂ formed as the opposite-side surface to substrate 10. In the first embodiment, second surface 17S₂ is a smooth flat surface, but asperities may be formed on second surface 17S₂ so as to correspond to the textures formed on the light-receiving surface of substrate 10.

In the first embodiment, first region 171 functions as an anti-reflection film. Accordingly, first region 171 prevents the light incident though the second surface 17S₂ and reflected from the first surface 17S₁ from passing out through the second surface 17S₂. Specifically, first region 171, at the interface with the second region 172, prevents light from leaking from first region 171 out to second region 172.

The refractive index of first region 171 is smaller than any of the refractive indexes of substrate 10, i-type amorphous semiconductor layer 15i, and amorphous semiconductor layer 16. The refractive index of first region 171 is smaller than that of second region 172.

Second surface 17S₂ is more acid-resistant than first surface 17S₁. Accordingly, second region 172 functions as an acid-resistant film. Second region 172 covers the light-receiving surface (including i-type amorphous semiconductor layer 15i, amorphous semiconductor layer 16, and first region 171) of substrate 10. Accordingly, second region 172 prevents acidic chemical liquid (e.g., etchant, or the like) used in the processes of manufacturing solar cell 100 from damaging the light-receiving-surface side of substrate 10.

Second region 172 is more acid-resistant than first region 171, so that the etching rate of second surface 17S₂ by an acidic solution is lower than the etching rate of first surface 17S₁. The resistivities of these regions within protection layer 17 against an acidic solution can be adjusted, for example, by making second region 172 have a higher silicon content rate than that of first region 171 in the case that protection layer 17 is formed from a material containing silicon. In this case, the silicon content rate of second region 172 may be uniform across the entire area of second region 172, or may gradually becomes higher farther away from the interface with the first region 171.

Each first region 171 and second region 172 can be formed from, for example, silicon nitride, silicon carbide, various types of resin, and various types of silicon. Note that the elements contained in first region 171 may be different from those contained in second region 172, but it is preferable that first region 171 and second region 172 contain the same elements.

As FIG. 3 shows, the thickness of first region 171 (denoted by α1 in FIG. 3) is larger than the thickness of second region 172 (denoted by α2). In the first embodiment, light transmission of first region 171 is higher than that of second region 172. Accordingly, the smaller the thickness α2 of second region 172 is, the higher the light transmission of protection layer 17 as a whole becomes.

### (Method of Manufacturing the Solar Cell)

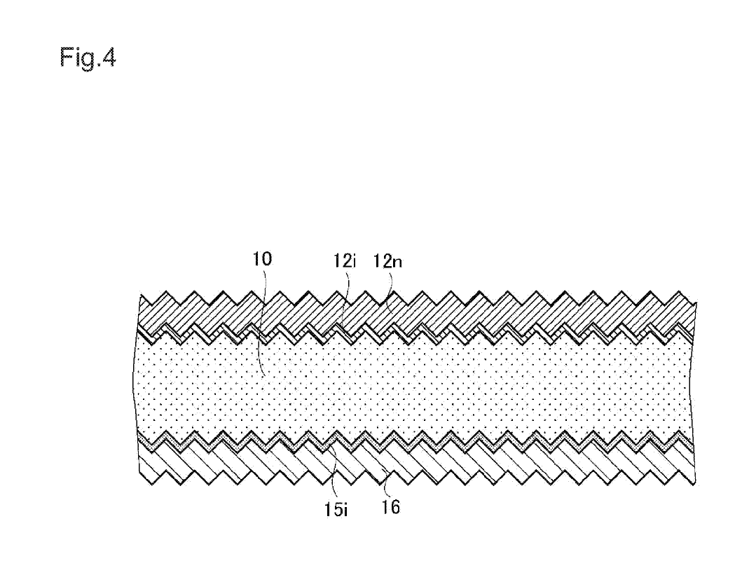

Next, a method of manufacturing solar cell 100 is described by referring to FIGS. 4 to 10. Each of FIGS. 4 to 10 is a sectional view of substrate 10 taken in the second direction.

First, semiconductor substrate 10 formed from an n-type monocrystalline silicon is washed with either an acidic or alkaline solution. Then, textures are formed by etching on both the light-receiving surface and on the back surface of substrate 10.

Next, as FIG. 4 shows, an i-type amorphous semiconductor layer is formed so as to cover substantially the entire surface of each of the back surface and the light-receiving surface of substrate 10 by the CVD method, and then, also by the CVD method, an n-type amorphous semiconductor layer is formed on each of the resulting i-type amorphous semiconductor layers. In this way, i-type amorphous semiconductor layer 12i is formed on the back surface of n-type substrate 10, and n-type amorphous semiconductor layer 12n is formed on i-type amorphous semiconductor layer 12i. Likewise, i-type amorphous semiconductor layer 15i is formed on the light-receiving surface of substrate 10, and then n-type amorphous semiconductor layer 16 is formed on i-type amorphous semiconductor layer 151.

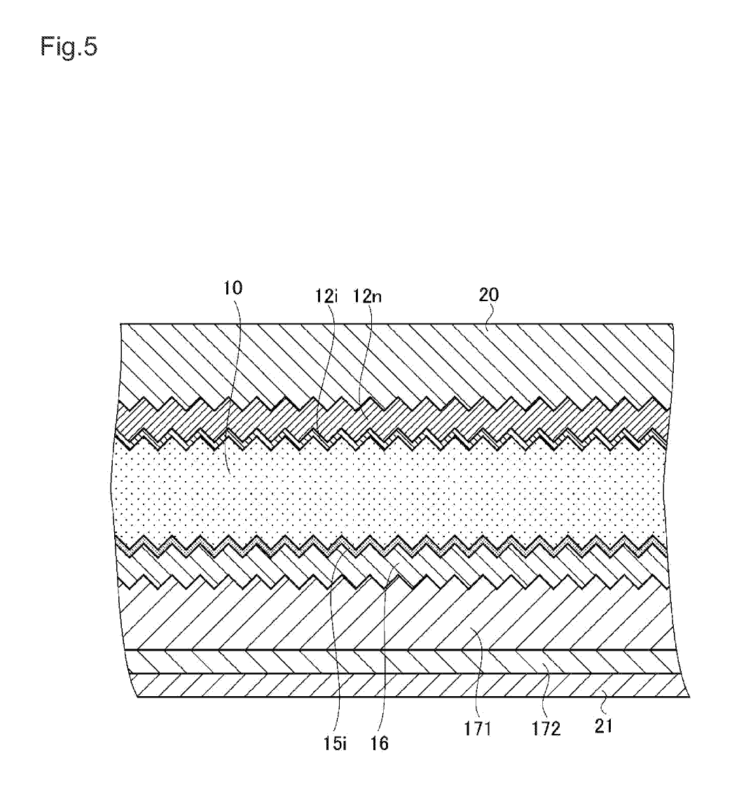

Next, as FIG. 5 shows, masking layer 20 is formed by the CVD method on n-type amorphous semiconductor layer 12n and an anti-reflection film (i.e., first region 171) is formed on amorphous semiconductor layer 16. Then, also by the CVD method, an acid-resistant film (i.e., second region 172) is formed on first region 171, and, after that, alkali-resistant film 21 is formed on second region 172. In this case, it is preferable that masking layer 20, first region 171, second region 172, and alkali-resistant film 21 be formed of the same materials while the component ratios of the materials are adjusted appropriately. In this way, the manufacturing processes become simpler. Consequently, masking layer 20, first region 171, second region 172, and alkali-resistant film 21 contain the same elements.

For example, while N₂, SiH₄, and NH₃ are being supplied, a silicon nitride film serving as masking layer 20 is formed on n-type amorphous semiconductor layer 12n by the PVCVD method and a silicon nitride film serving as the anti-reflection film (i.e., first region 171) is formed on amorphous semiconductor layer 16 by the same method.

Then, while N₂, SiH₄, and NH₃ are being supplied, a silicon nitride film serving as the acid-resistant film (i.e., second region 172) is formed on first region 171 by the PVCVD method. It is preferable that the thickness of this silicon nitride film, serving as the acid-resistant film, be equal to or larger than 20 nm, but this is not the only possible thicknesses.

Then, while N₂, SiH₄, and NH₃ are being supplied, a silicon nitride film serving as alkali-resistant film 21 is formed on second region 172 by the PVCVD method. It is preferable that the thickness of this silicon nitride film, serving as the alkali-resistant film, be equal to or larger than 10 nm, but this is not the only possible thicknesses.

The flow-rate ratio X of SiH₄ to NH₃ during the formation of second region 172 is larger than the flow-rate ratio Y of SiH₁ to NH₃ during the formation of masking layer 20 and first region 171. The silicon nitride film thus formed by increasing the silicon content rate of second region 172 becomes acid-resistant, or, to put it differently, has a lower etching rate. In addition, the refractive index of second region 172 is larger than the refractive index of first region 171. Note that the flow-rate ratio X is preferably equal to or smaller than 0.3, but this is not the only possible flow-rate ratio X.

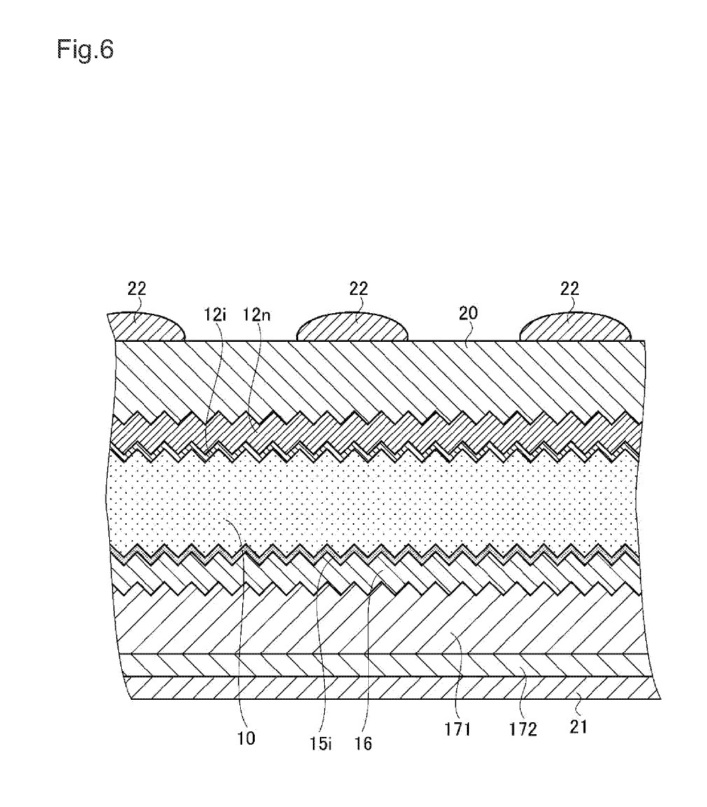

Next, as FIG. 6 shows, etching paste 22 is applied, in a predetermined pattern, to the surface of masking layer 20 by a printing method or the like. The above-mentioned predetermined pattern refers to a pattern corresponding to p-type amorphous semiconductor layer 11p formed in a comb-tooth-like shape.

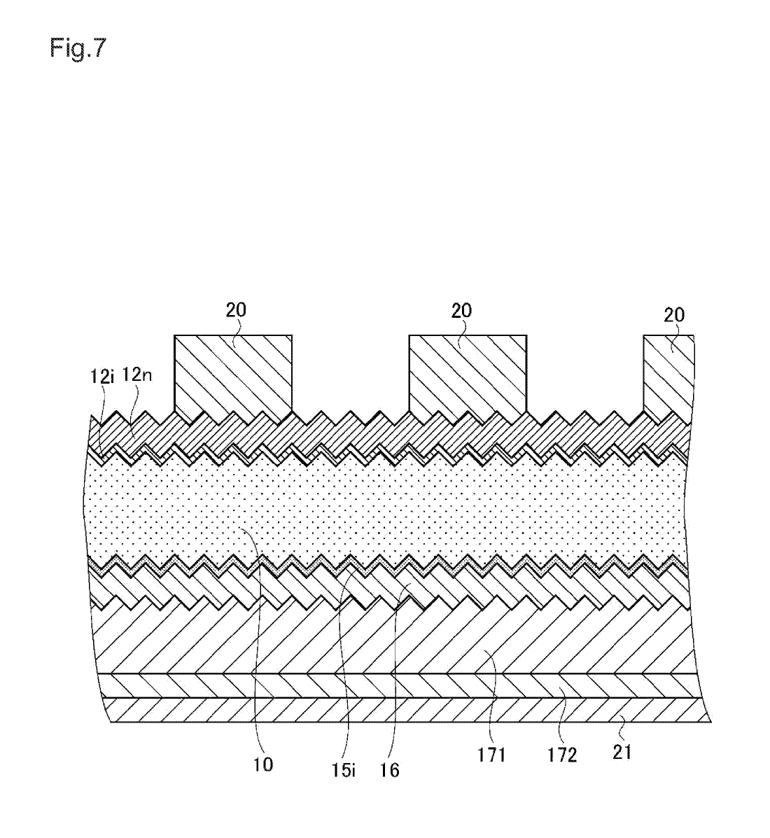

Next, as FIG. 7 shows, etching paste 22 is heated (e.g., at a temperature of approximately 200° C. or lower, and for 5 minutes or shorter) to etch masking layer 20 in the direction perpendicular to the plane of masking layer 20.

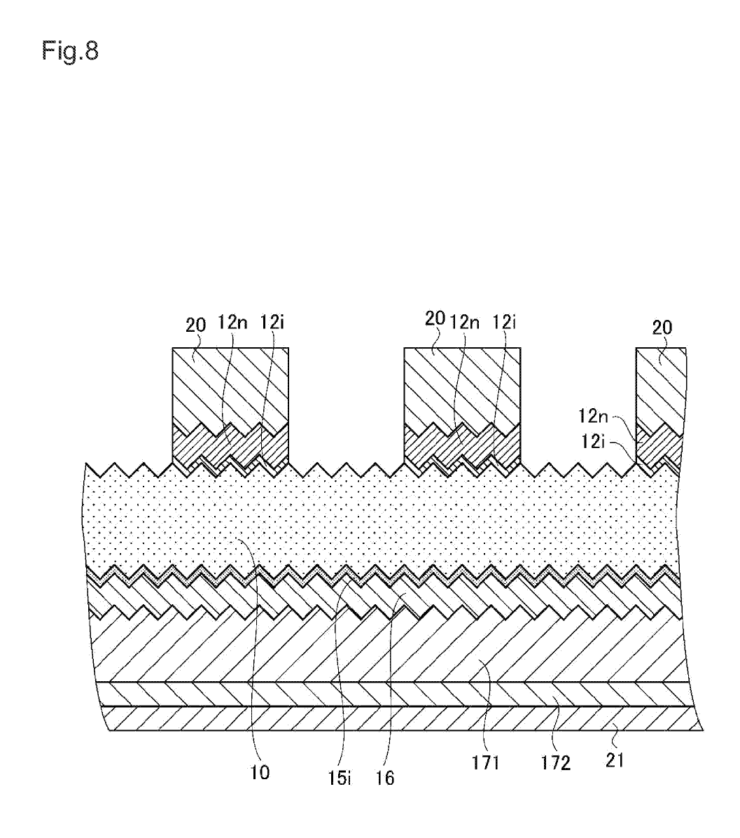

Next, as FIG. 8 shows, i-type amorphous semiconductor layer 12i and n-type amorphous semiconductor layer 12n are etched using an alkali etchant (e.g., a sodium hydroxide solution of approximately 1% concentration, at a temperature of approximately 70° C.). For example, the etching time is approximately 1 minute or longer. In this way, i-type amorphous semiconductor layer 12i and n-type amorphous semiconductor layer 12n are patterned in the predetermined pattern. During the etching process, alkali-resistant film 21 covers the light-receiving-surface side of substrate 10. Alkali-resistant film 21 prevents the alkali etchant from impairing the acid resistance of second region 172, the anti-reflective properties of first region 171, and the passivation characteristics of i-type amorphous semiconductor layer 15i and of amorphous semiconductor layer 16. In addition, alkali-resistant film 21 prevents the alkali etchant from damaging the light-receiving surface of substrate 10.

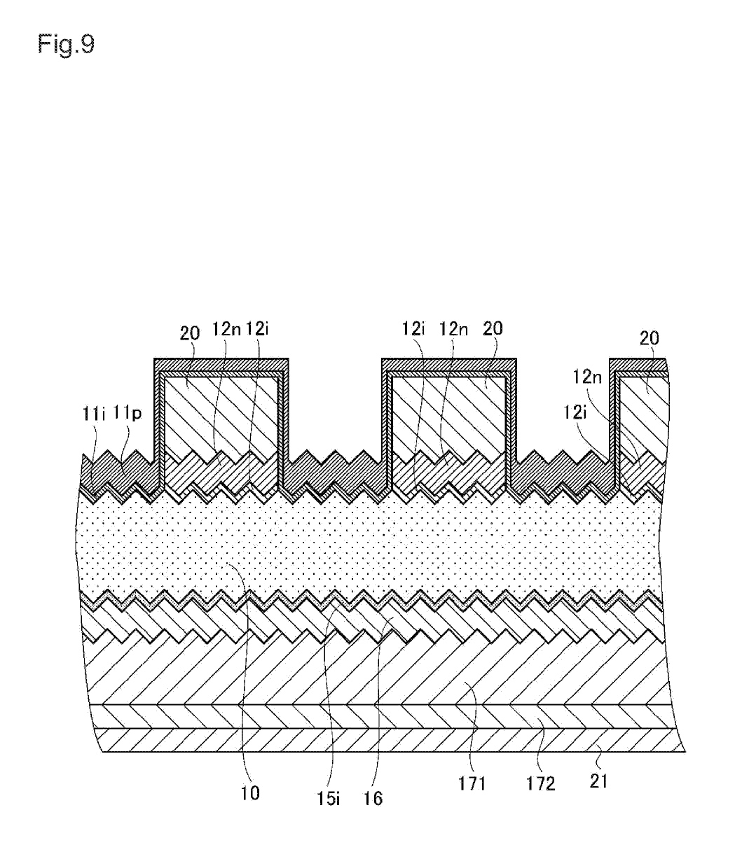

Next, as FIG. 9 shows, i-type amorphous semiconductor layer 11i and p-type amorphous semiconductor layer 11p are formed in this order, by the CVD method, at the back-surface side of substrate 10. I-type amorphous semiconductor layer iii and p-type amorphous semiconductor layer 11p are formed to bridge i-type amorphous semiconductor layer 12i, n-type amorphous semiconductor layer 12n, and masking layer 20 from the back surface of substrate 10. In other words, both i-type amorphous semiconductor layer 11i and p-type amorphous semiconductor layer 11p are formed so as to cover, from above the back surface of substrate 10, the surface where i-type amorphous semiconductor layer 12i, n-type amorphous semiconductor layer 12n, and masking layer 20 are formed one upon another.

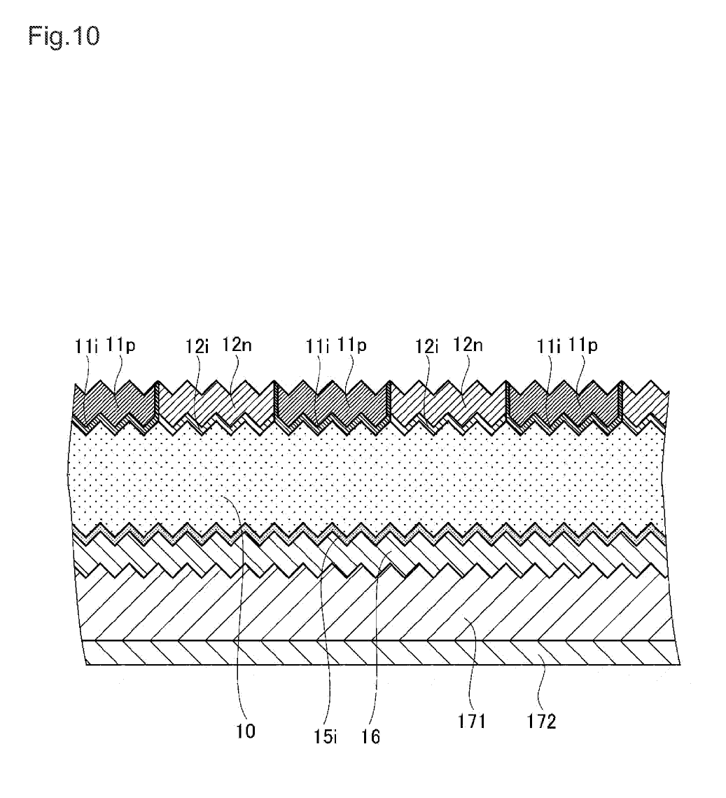

Next, as FIG. 10 shows, masking layer 20 is etched using an acidic etchant (e.g., a hydrofluoric acid solution of approximately 0.4% concentration). For example, the etching time is in a range from 30 to 60 seconds, approximately. In this way, i-type amorphous semiconductor layer 11i and p-type amorphous semiconductor layer 11p, which are formed so as to cover masking layer 20, are removed together with masking layer 20. In addition, alkali-resistant film 21 is also removed together with masking layer 20. Note that acid-resistant second region 172 covers the light-receiving surface side of substrate 10. Accordingly, second region 172 prevents the acidic etchant from impairing the anti-reflective properties of first region 171, the passivation characteristics of i-type amorphous semiconductor layer 15i and of amorphous semiconductor layer 16. In addition, second region 172 prevents the acidic etchant from damaging the light-receiving surface of substrate 10.

Next, i-type amorphous semiconductor layer 11i and p-type amorphous semiconductor layer 11p are separated from i-type amorphous semiconductor layer 12i and n-type amorphous semiconductor layer 12n by exposing the boundary between layers 11i, 11p and layers 12i, 12n to laser light.

Next, the CVD method, the sputtering method, the vapor deposition method, the plating method, the printing method, or the like, is used to form a contact layer formed from such material as aluminum on each of p-type amorphous semiconductor layer 11p and n-type amorphous semiconductor layer 12n. Then, a low-resistivity layer formed from such material as copper is formed on each of the contact layers. Thus formed are p-side fine line-shaped electrodes 13p, n-side fine line-shaped electrodes 13n, p-side connection electrode 14p, and n-side connection electrode 14n.

Note that a solar cell module as follows may be formed. Specifically, plural solar cells 100 that are electrically connected to one another by means of wiring materials are placed between a light-receiving surface-side protection material, and a back-surface-side protection material. Plural solar cells 100 thus placed are then sealed using a sealing material.

### ADVANTAGEOUS EFFECTS

In solar cell 100 according to the first embodiment, second surface 17S₂ of protection layer 17 is more acid-resistant than first surface 17S₁.

Accordingly, in the processes of manufacturing solar cell 100, the acidic chemical solution, such as an acidic etchant, is prevented from damaging the light-receiving-surface side of substrate 10. In addition, protection layer 17 needs to be formed only once in the processes of manufacturing solar cell 100 because protection layer 17 is acid-resistant. It is not necessary to form protection layer 17 more than once. So, the manufacturing productivity of solar cell 100 is improved.

In addition, protection layer 17 according to the first embodiment includes first region 171 having first surface 17S₁ formed therein, and second region 172 having second surface 17S₂ formed therein. First region 171 functions as an anti-reflection film.

Acid-resistant second region 172 is formed on first region 171 serving as an anti-reflection film. Accordingly, acid-resistant second region 172 does not have to be removed to form an anti-reflection film. In addition, second region 172 protects first region 171 against acidic chemical solutions, so that the anti-reflective properties of first region 171 are prevented from being impaired.

In addition, if first region 171 contains the same elements as those contained in second region 172, or, to put it differently, if first region 171 and second region 172 are made of the same materials, the manufacturing productivity of solar cell 100 is further improved.

For example, if silicon nitride is used for this purpose, first region 171 and second region 172 can be formed consecutively by adjusting the flow-rate ratios of SiH₄ to NH₃. Specifically, the flow-rate ratio X during the formation of second region 172 is made larger than the flow-rate ratio Y during the formation of first region 171. The silicon content rate of second region 172 is thus increased, and thereby second region 172 can be made acid-resistant in a simple manner. Consequently, the formation of first region 171 serving as an anti-reflection film and the formation of second region 172 serving as an acid-resistant film can be made by consecutive processes.

In addition, in solar cell 100 according to the first embodiment, a passivation layer formed by i-type amorphous semiconductor layer 15i and amorphous semiconductor layer 16 is formed between the light-receiving surface of substrate 10 and protection layer 17. Protection layer 17 covers the passivation layer thus formed, so that the protection layer 17 prevents acidic chemicals from impairing passivation characteristics of the passivation layer.

In addition, in the method of manufacturing solar cell 100 according to the first embodiment, alkali-resistant film 21 covers second region 172. Accordingly, alkali-resistant film 21 prevents the alkali etchant from impairing the acid resistivity of second region 172, the anti-reflective properties of first region 171, and the passivation characteristics of i-type amorphous semiconductor layer 15i and of amorphous semiconductor layer 16. In addition, alkali-resistant film 21 also prevents the alkali etchant from damaging the light-receiving surface of substrate 10.

### Second Embodiment

Next, a second embodiment of the invention is described by referring to the drawings. The description that follows focuses mainly on the differences between embodiments 1 and 2. Specifically, in the second embodiment, the n-type semiconductor region and the p-type semiconductor region are formed at the back-surface side of substrate 10 by thermal diffusion.

### (Configuration of the Solar Cell)

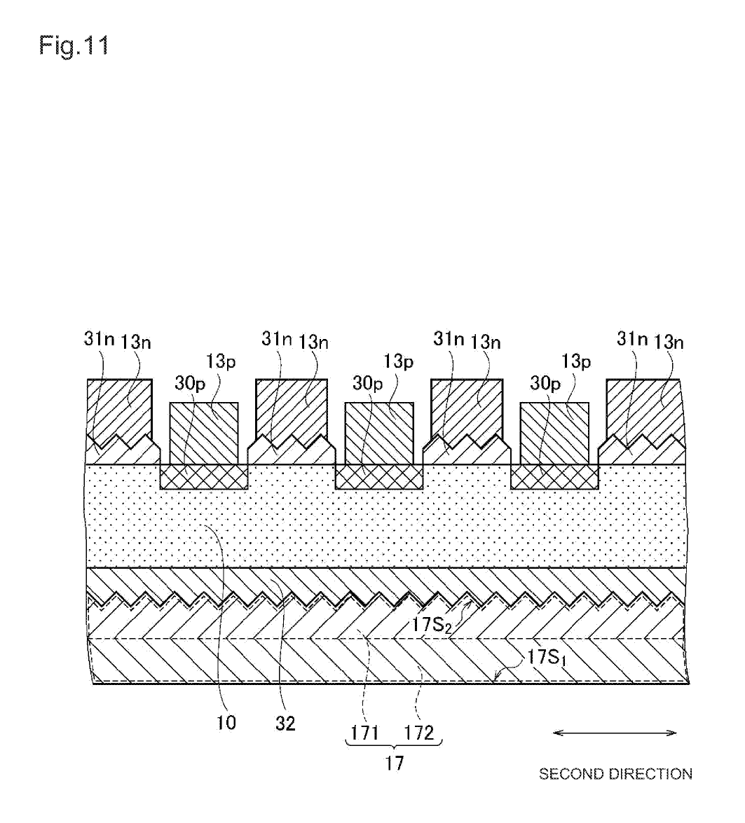

The configuration of solar cell 100 according to the second embodiment is described by referring to FIG. 11.

As FIG. 11 shows, solar cell 100 includes substrate 10 of either n-type or p-type, p-type diffusion region 30p, n-type diffusion region 31n, and passivation layer 32. In the second embodiment, p-type diffusion region 30p corresponds to the p-type semiconductor region, and n-type diffusion region 31n corresponds to the n-type semiconductor region.

P-type diffusion region 30p is a high-concentration p-type diffusion region formed on the back surface of substrate 10 by doping a p-type dopant by the thermal diffusion method. P-type diffusion region 30p is formed in a comb-tooth-like shape in a plan view obtained by viewing solar cell 100 from the back-surface side.

N-type diffusion region 31n is a high-concentration n-type diffusion region formed on the back surface of substrate 10 by doping an n-type dopant by the thermal diffusion method. N-type diffusion region 31n is formed in a comb-tooth-like shape in a plan view obtained by viewing solar cell 100 from the back-surface side.

Passivation layer 32 is a high-concentration n-type diffusion region formed on the light-receiving surface of substrate 10 by the thermal diffusion method by doping a dopant that has the same conductive type that substrate 10 has. Passivation layer 32 is formed so as to cover substantially the entire surface of the light-receiving surface of substrate 10.

The rest of the configuration is similar to the corresponding configuration of the first embodiment described above.

### (Method of Manufacturing the Solar Cell)

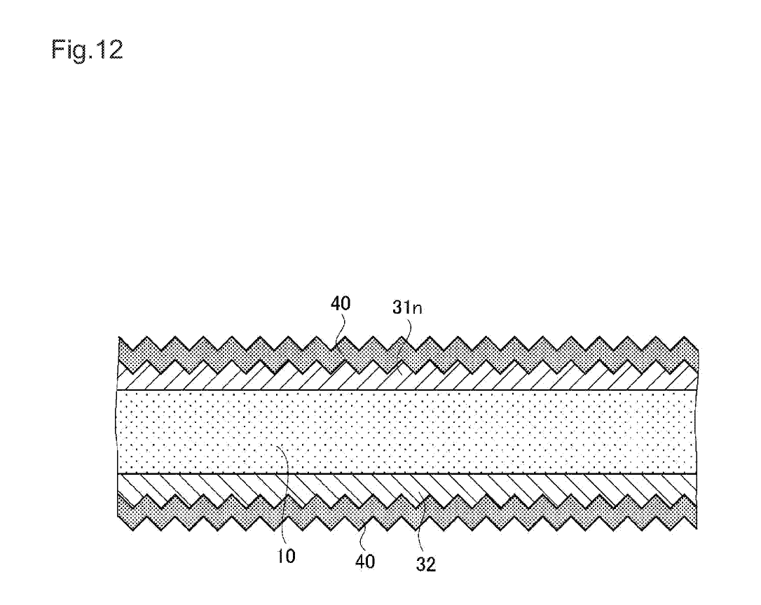

Next, a method of manufacturing solar cell 100 is described by referring to FIGS. 12 to 17. Each of FIGS. 12 to 17 is a sectional view of substrate 10 taken in the second direction.

First, semiconductor substrate 10 formed from an n-type monocrystalline silicon is washed with either an acidic or an alkaline solution. Then, textures are formed by etching on both the light-receiving surface and on the back surface of substrate 10.

Next, as FIG. 12 shows, diffusion layers 40 containing an n-type dopant are formed respectively on the back surface and on the light-receiving surface of substrate 10 by the CVD method or the like. Diffusion layers 40 are made, for example, from phospho-silicate glass (PSG). Then, by heating diffusion layers 40 at a high temperature (specifically from 700° C. to 1000° C.) for 60 minutes or shorter, the n-type dopant is thermally diffused within the back surface and the light-receiving surface of substrate 10. In this way, n-type diffusion region 31n and passivation layer 32 are formed. Note that diffusion layers 40 that remain are removed using hydrogen fluoride or the like.

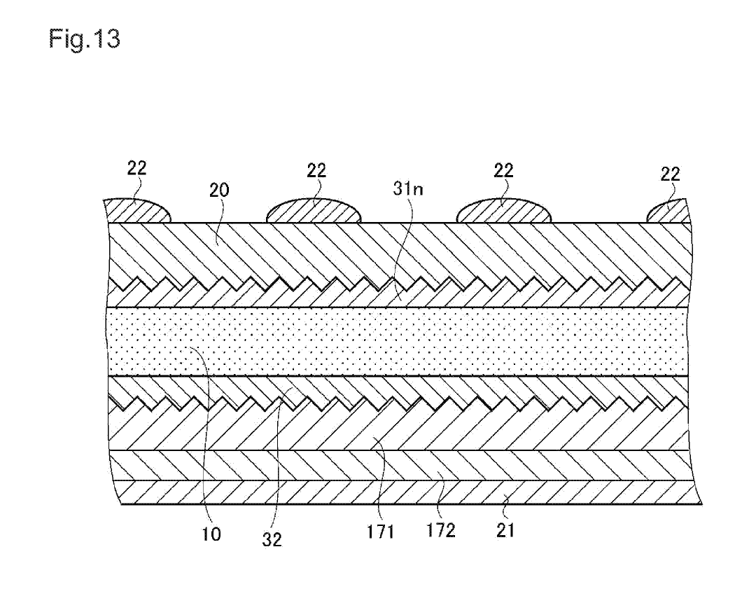

Next, as FIG. 13 shows, masking layer 20 is formed on n-type diffusion region 31n located at the back surface side of substrate 10 and an anti-reflection film (i.e., first region 171) is formed on passivation layer 32 located at the light-receiving-surface side of substrate 10 by the CVD method. Then, an acid-resistant film (i.e., second region 172) is formed on first region 171 and then alkali-resistant film 21 is formed on second region 172 by the CVD method. After that, etching paste 22 is applied, in a predetermined pattern, to the surface of masking layer 20 by the printing method or the like.

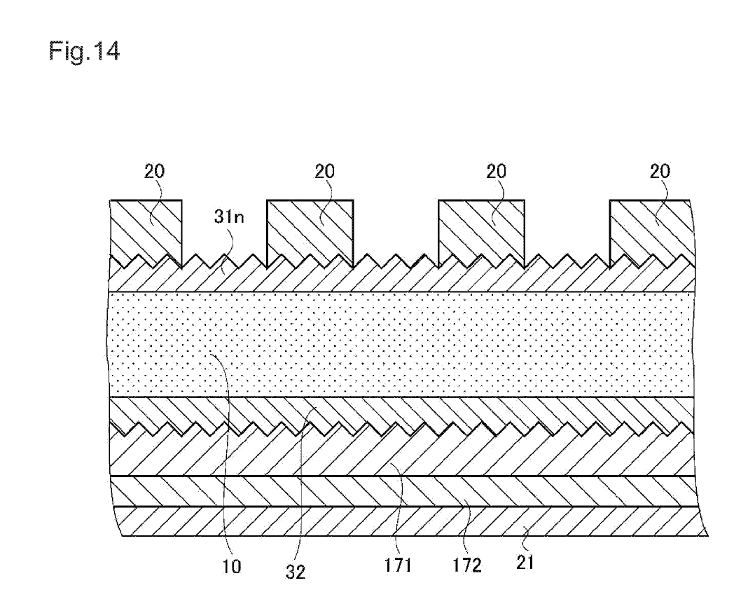

Next, as FIG. 14 shows, etching paste 22 is heated (e.g., at a temperature of approximately 200° C. or lower, and for 5 minutes or shorter) to etch masking layer 20 in the direction perpendicular to the plane of masking layer 20.

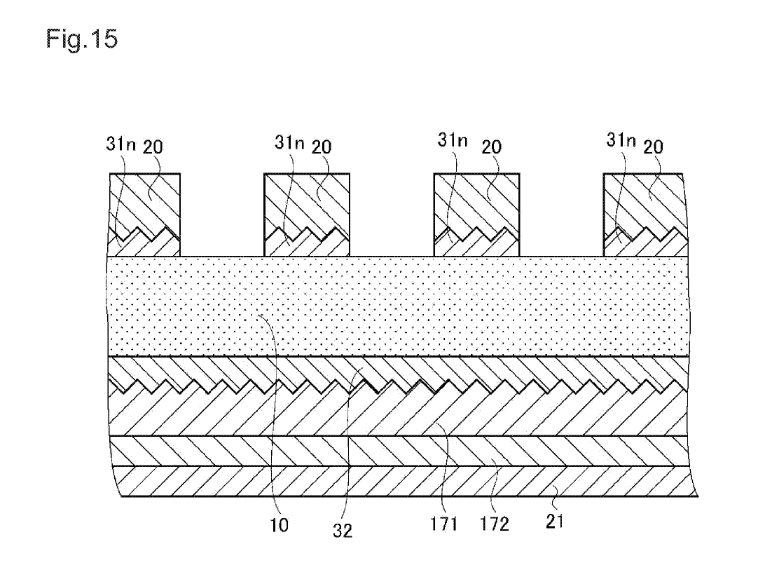

Next, as FIG. 15 shows, n-type diffusion region 31n is etched using an alkali etchant (e.g., a sodium hydroxide solution of an approximately 1% concentration and at a temperature of approximately 70° C.). For example, the etching time is approximately 1 minute or longer. In this way, n-type diffusion region 31n is patterned in a predetermined pattern. During the etching process, alkali-resistant film 21 covers the light-receiving-surface side of substrate 10. Alkali-resistant film 21 prevents the alkali etchant from impairing the acid resistance of second region 172, the anti-reflective properties of first region 171, and the passivation characteristics of passivation layer 32. In addition, alkali-resistant film 21 prevents the alkali etchant from damaging the light-receiving surface of substrate 10.

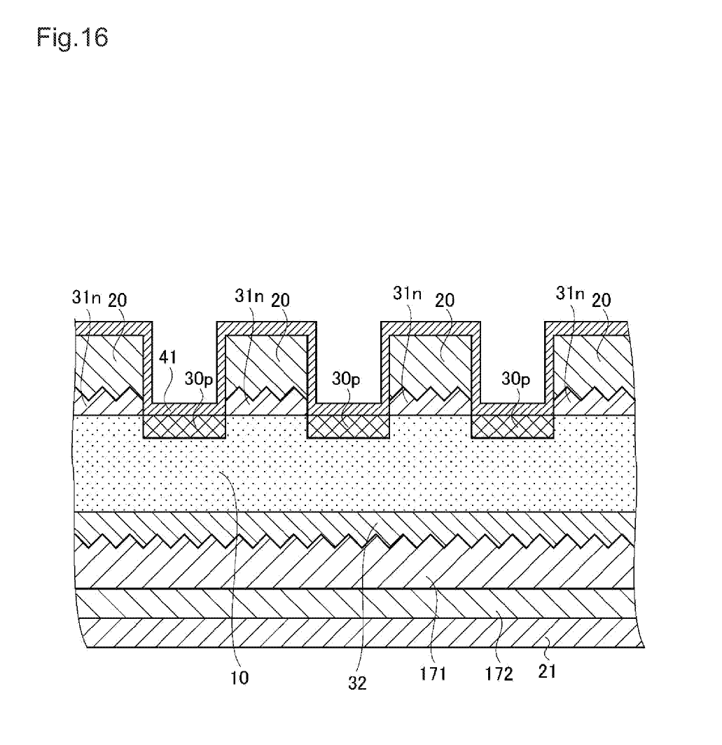

Next, as FIG. 16 shows, diffusion layer 41 containing a p-type dopant is formed on the back surface of substrate 10 by the CVD method or the like. Diffusion layer 41 is formed, for example, from boron-silicate glass (BSG). Then, by heating diffusion layer 41 at a high temperature (specifically, from 700° C. to 1000° C.) for 60 minutes or shorter, the p-type dopant is thermally diffused within the back surface of substrate 10. In this way, p-type diffusion region 30p is formed.

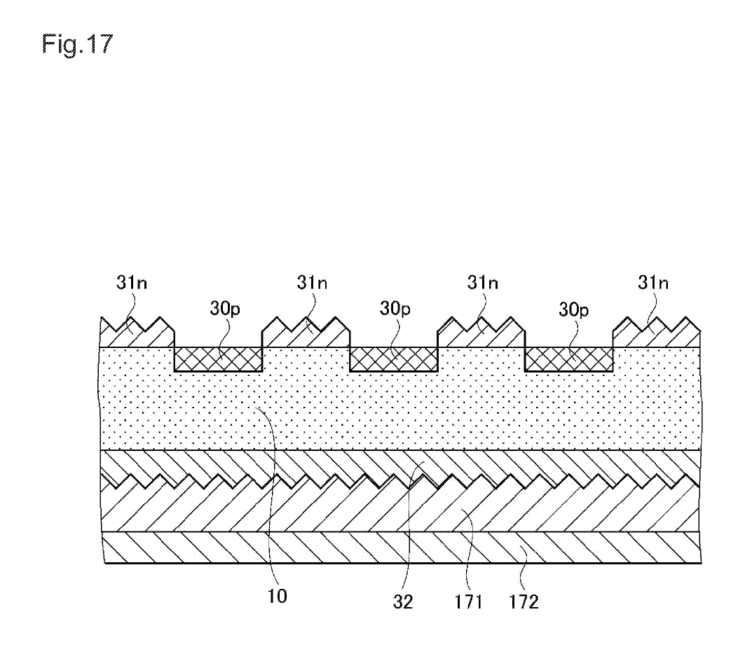

Next, as FIG. 17 shows, masking layer 20 is etched using an acidic etchant (e.g., a hydrofluoric acid solution of approximately 0.4% concentration). For example, the etching time is in a range from 30 to 60 seconds, approximately. In this way, diffusion layer 41 that is formed so as to cover masking layer 20 is removed together with masking layer 20. In addition, alkali-resistant film 21 is also removed together with masking layer 20. Note that acid-resistant second region 172 covers the light-receiving-surface side of substrate 10. Second region 172 prevents the acidic etchant from impairing the anti-reflective properties of first region 171, and the passivation characteristics of passivation layer 32. In addition, second region 172 prevents the acidic etchant from damaging the light-receiving surface of substrate 10.

Next, the CVD method, the sputtering method, the vapor deposition method, the plating method, the printing method, or the like, is used to form a contact layer made of such material as aluminum on each of p-type diffusion region 30p and n-type diffusion region 31n. Then, a low-resistivity layer made of such material as copper is formed on each of the contact layers. Thus formed are p-side fine line-shaped electrodes 13p, n-side fine line-shaped electrodes 13n, p-side connection electrode 14p, and n-side connection electrode 14n.

### ADVANTAGEOUS EFFECTS

In solar cell 100 according to the second embodiment, second surface 17S₂ of protection layer 17 is acid-resistant. Accordingly, in the processes of manufacturing solar cell 100, second surface 17S₂ prevents the acidic chemical solution, such as an acidic etchant, from damaging light-receiving-surface side of substrate 10. In addition, protection layer 17 needs to be formed only once in the processes of manufacturing solar cell 100 because protection layer 17 is acid-resistant. It is not necessary to form protection layer 17 more than once. So, the manufacturing productivity of solar cell 100 is improved.

### Other Embodiments

In the above-described embodiments, n-type and p-type semiconductor regions are formed by the CVD method or by the thermal diffusion method, but these methods are not the only methods that can be used. One of the other employable methods to form n-type and p-type semiconductor regions is the laser-doping method, in which a diffusion layer containing a dopant is irradiated with laser light.

In addition, in the above-described embodiments, solar cell 100 includes a passivation layer and an anti-reflection film, but this is not the only possible configuration. It is possible that solar cell 100 includes only one of the passivation layer and the anti-reflection film, or it is also possible that solar cell 100 includes neither one of the passivation layer and the anti-reflection film. In other words, protection layer 17 may include only second region 172.

### [Verification Experiments]

Experiments were carried out to examine the relationship between various film-forming conditions and the characteristics of the acid-resistant SiN film (i.e., second region 172) and of the alkali-resistant SiN film (i.e., alkali-resistant film 21).

### (1) Acid-Resistant SiN Film

### (1-1) Etching Rate of Acid-Resistant SiN Film

Acid-resistant SiN films of Samples 1 to 5 are formed respectively on mirror-finished Si substrates by the PVCVD method under the film-forming conditions shown in Table 1.

TABLE 1

| | | | N₂ | SiH₄ | NH₃ | NH₃/SiH₄ | RF | | Distance |
|---|---|---|---|---|---|---|---|---|---|
| | Deposition | Substrate | flow | flow | flow | flow- | power | | from |
| | time | temperature | rate | rate | rate | rate | density | Pressure | substrate |
| | (min) | (° C.) | (scc) | (scc) | (scc) | ratio | (mw/cm²) | (torr) | (mils) |
| Sample 1 | 360 | 200 | 1000 | 60 | 60 | 1 | 55 | 2 | 415 |
| Sample 2 | 360 | 200 | 1000 | 60 | 40 | 0.7 | 55 | 2 | 415 |
| Sample 3 | 360 | 200 | 1000 | 60 | 20 | 0.3 | 55 | 2 | 415 |
| Sample 4 | 360 | 200 | 1000 | 60 | 10 | 0.16 | 55 | 2 | 415 |
| Sample 5 | 360 | 200 | 1000 | 60 | 1 | 0.016 | 55 | 2 | 415 |

As Table 1 shows, the flow-rate ratio of SiH₄ to NH₃ is gradually decreased from Sample 1 to Sample 5. To put it differently, the supply of Si is gradually increased from Sample 1 to Sample 5. Each of Samples 1 to 5 thus prepared is subjected to an etching process using hydrofluoric acid having a concentration of 0.4% for 60 seconds. The film thickness of each of Samples 1 to 5 is measured both before and after the etching.

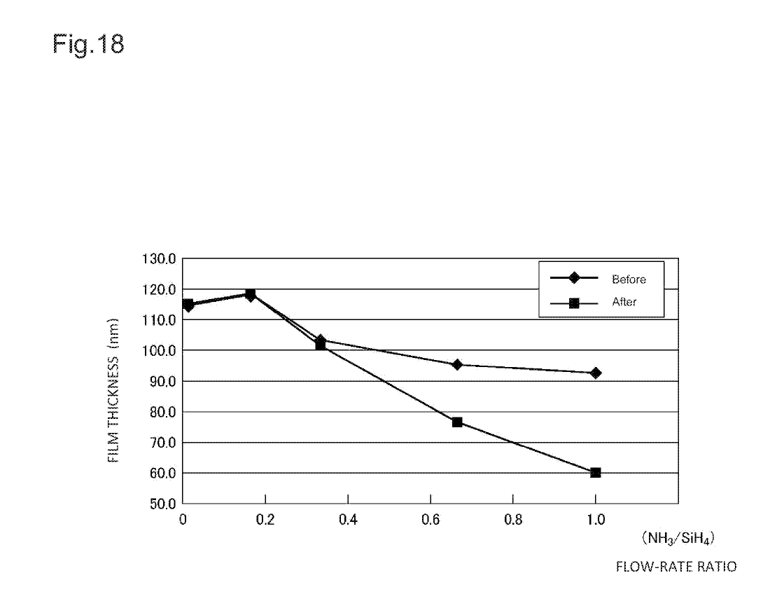

FIG. 18 is a diagram illustrating the relationship between the film thickness and the flow-rate ratio both before and after the etching process. As FIG. 18 shows, the etching rates of Samples 3 to 5 are lower than the etching rates of Samples 1 and 2. The results show that Samples 3 to 5 are more acid-resistant than Samples 1 and 2. Accordingly, the flow-rate ratio of SiH₄ to NH₃ is preferably 0.3 or smaller.

### (1-2) Refractive Index of Acid-Resistant SiN Film

The refractive indexes of Samples 1 to 5 are measured both before and after the etching process.

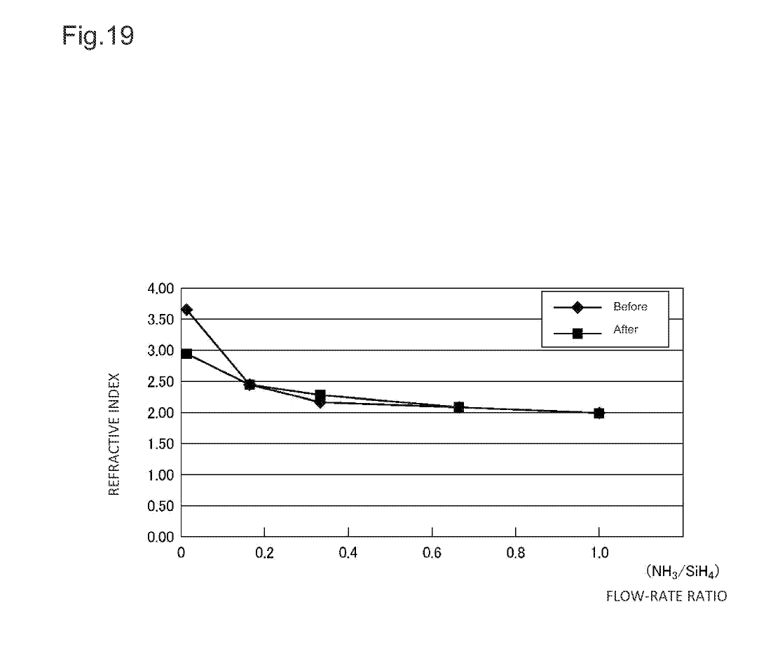

FIG. 19 is a diagram illustrating the relationship between the refractive index and the flow-rate ratio both before and after the etching process. As FIG. 19 shows, more acid-resistant Samples 3 to 5 keep their respective refractive indexes larger than 2.2 both before and after the etching process. In addition, sufficient acid-resistivity can be obtained under the condition of a refractive index that is 2.2 or larger.

### (1-3) Minimum Film Thickness of Acid-Resistant SiN Film

Acid-resistant SiN films of Samples 6 to 10 are formed respectively on anti-reflection films formed on mirror-finished Si substrates. The acid-resistant SiN films are formed by the PVCVD method under the film-forming conditions shown in Table 2.

TABLE 2

| | | | N₂ | SiH₄ | NH₃ | NH₃/SiH₄ | RF | | Distance |
|---|---|---|---|---|---|---|---|---|---|
| | Deposition | Substrate | flow | flow | flow | flow- | power | | from |
| | time | temperature | rate | rate | rate | rate | density | Pressure | substrate |
| | (min) | (° C.) | (scc) | (scc) | (scc) | ratio | (mw/cm²) | (torr) | (mils) |
| Sample 6 | 0 | 200 | 1000 | 60 | 20 | 0.3 | 55 | 2 | 415 |
| Sample 7 | 10 | 200 | 1000 | 60 | 20 | 0.3 | 55 | 2 | 415 |
| Sample 8 | 15 | 200 | 1000 | 60 | 20 | 0.3 | 55 | 2 | 415 |
| Sample 9 | 30 | 200 | 1000 | 60 | 20 | 0.3 | 55 | 2 | 415 |
| Sample 10 | 60 | 200 | 1000 | 60 | 20 | 0.3 | 55 | 2 | 415 |

As Table 2 shows, the deposition time of Samples 6 to 10 is gradually increased. Thus, the film thickness of Samples 6 to 10 becomes gradually larger. Specifically, the minimum film thickness of Sample 6 is 0 nm, the minimum film thickness of Sample 7 is 3 nm, the minimum film thickness of Sample 8 is 5 nm, the minimum film thickness of Sample 9 is 10 nm, and the minimum film thickness of Sample 10 is 20 nm. The “minimum film thickness” refers to the thickness of the thinnest portion of the acid-resistant SiN film formed on the anti-reflection film.

Each of Samples 6 to 10 is subjected to an etching process using hydrofluoric acid having a concentration of 0.4% for 60 seconds.

After the etching process, whether the anti-reflection film still remains or not is checked for each of Samples 6 to 10.

Each of Samples 6 to 9 has no anti-reflection film remaining. In Sample 10, however, a portion of the anti-reflection film still remains after the etching process. Accordingly, the film thickness of the acid-resistant SiN film is preferably 20 nm or larger.

### (2) Alkali-Resistant SiN Film

### (2-1) Etching Rate of Alkali-Resistant SiN Film

Alkali-resistant SiN films of Samples 11 to 13 are formed respectively on mirror-finished Si substrates by the PVCVD method under the film-forming conditions shown in Table 3.

TABLE 3

| | | | N₂ | SiH₄ | NH₃ | NH₃/SiH₄ | RF | | Distance |
|---|---|---|---|---|---|---|---|---|---|
| | Deposition | Substrate | flow | flow | flow | flow- | power | | from |
| | time | temperature | rate | rate | rate | rate | density | Pressure | substrate |
| | (min) | (° C.) | (scc) | (scc) | (scc) | ratio | (mw/cm²) | (torr) | (mils) |
| Sample 11 | 360 | 200 | 1000 | 60 | 100 | 1.7 | 55 | 2 | 415 |
| Sample 12 | 360 | 200 | 1000 | 40 | 100 | 2.5 | 55 | 2 | 415 |
| Sample 13 | 360 | 200 | 1000 | 20 | 100 | 5.0 | 55 | 2 | 415 |

As Table 3 shows, the flow-rate ratio of SiH₄ to NH₃ is gradually increased from Sample 11 to Sample 13. To put it differently, the supply of Si is gradually decreased from Sample 11 to Sample 13. Each of Samples 11 to 13 thus prepared is subjected to an etching process using sodium hydroxide (at a temperature of 70° C. and having a concentration of 1%) for 5 minutes. The film thickness of each of Samples 11 to 13 is measured both before and after the etching.

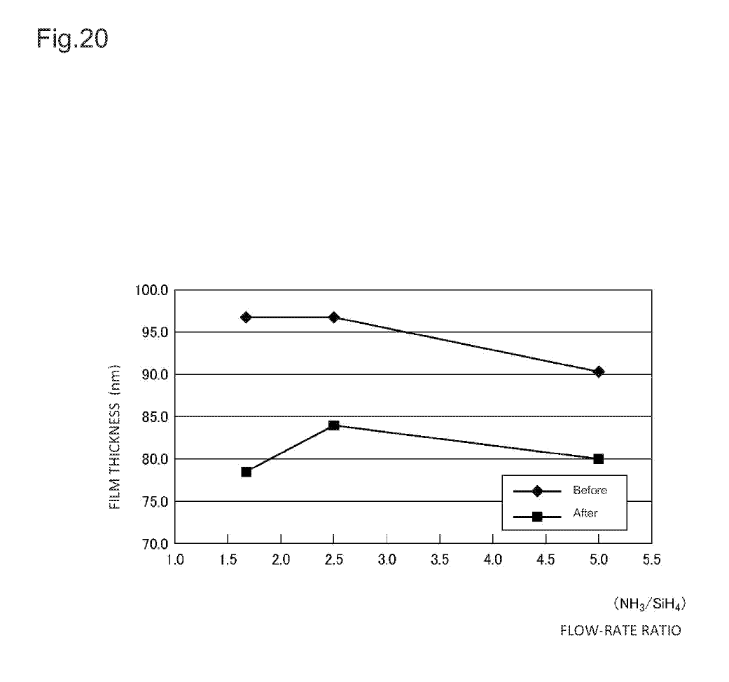

FIG. 20 is a diagram illustrating the relationship between the film thickness and the flow-rate ratio both before and after the etching process. As FIG. 20 shows, each of Samples 11 to 13 has sufficient film thickness even after the etching process.

The etching rate of Sample 11 is 3.7 nm/min, the etching rate of Sample 12 is 2.5 nm/min, and the etching rate of Sample 13 is 2.0 nm/min. In the actual processes of manufacturing solar cells, it takes only two or three minutes approximately to perform the etching process using an alkali chemical solution. Accordingly, the alkali-resistant SiN film has only to have a thickness within a range approximately from 10 to 20 nm.

Note that Sample 11 represents the film-forming conditions for forming a common anti-reflection film or a common masking layer.

As described above, according to the embodiments, a solar cell with increased manufacturing productivity can be provided.

The invention includes other embodiments in addition to the above-described embodiments without departing from the spirit of the invention. The embodiments are to be considered in all respects as illustrative, and not restrictive. The scope of the invention is indicated by the appended claims rather than by the foregoing description. Hence, all configurations including the meaning and range within equivalent arrangements of the claims are intended to be embraced in the invention.

What is claimed is:

1. A solar cell comprising:
a semiconductor substrate having a light-receiving surface and a back surface disposed at the opposite side from the light-receiving surface;
a n-type semiconductor region and a p-type semiconductor region both formed on the back surface; and
a protection layer formed on the light-receiving surface, the protection layer includes a first surface formed on the semiconductor substrate side and a second surface formed on the opposite side from the first surface, and the second surface has a higher acid-resistance than the first surface.

2. The solar cell according to claim 1,
wherein the protection layer includes a first region forming the first surface and a second region forming the second surface,
wherein the first region functions as an anti-reflection film that prevents the light incident though the second surface and reflected from the first surface from passing out through the second surface.

3. The solar cell according to claim 2, wherein
a silicon content rate of the second region is higher than that of the first region.

4. The solar cell according to claim 3,
wherein a silicon content rate of the second region gradually becomes higher farther away from an interface with the first region.

5. The solar cell according to claim 2,
wherein elements of the second region are the same as that of the first region.

6. The solar cell according to claim 5,
wherein the second region is formed from silicon nitride.

7. The solar cell according to claim 2,
wherein the thickness of the second region is 20 nm or larger.

8. The solar cell according to claim 1,
wherein the etching rate of the second surface is smaller than that of the first surface.

9. The solar cell according to claim 2,
wherein the second region has a higher acid-resistance than that of the first region.

10. The solar cell according to claim 2,
wherein the refractive index of the first region is smaller than that of the semiconductor substrate.

11. The solar cell according to claim 2,
wherein the refractive index of the first region is larger than that of the second region.

12. The solar cell according to claim 2,
wherein the thickness of the second region is smaller than that of the first region.

13. The solar cell according to claim 2,
wherein a passivation layer is formed between the semiconductor substrate and the protection layer.

14. A method of manufacturing a solar cell, comprising steps of:
forming a semiconductor substrate having a light-receiving surface and a back surface disposed at the opposite side from the light-receiving surface;
forming a n-type semiconductor region and a p-type semiconductor region on the back surface; and
forming a protection layer on the light-receiving surface, the forming the protection layer comprising:
forming a first surface formed on the semiconductor substrate side; and
forming a second surface formed on the opposite side from the first surface, the second surface has a higher acid-resistance than the first surface.

15. The method of manufacturing a solar cell according to claim 14,
wherein the step of forming the n-type semiconductor region on the back surface further includes:
forming a masking layer on the n-type semiconductor region using the same elements as used for the first region on the light-receiving-surface side, the second region, and an alkali-resistant film; and
removing the masking layer and the alkali-resistant film by an acidic etchant.
